(19) United States
(12) Patent Application Publication
(10) Pub. No.: US 2007/0089982 A1
(43) Pub. Date: Apr. 26, 2007

(54) Sputtering target and method/apparatus for cooling the target

(76) Inventors: Hendryk Richert, Jena (DE); Patrick Wieland, Sandersdorf (DE); Armin Schmidt, Zeulenroda (DE); Gerald Janicke, Bobbau (DE); Roland Weidl, Bollberg (DE); Bernd E. Gruenler, Zeulenroda (DE); Hans-Jurgen Tiller, Jena (DE); Uwe Kriltz, Jena (DE)

Correspondence Address: NIXON & VANDERHYE, PC, 901 NORTH GLEBE ROAD, 11TH FLOOR, ARLINGTON, VA, 22203, US

(21) Appl. No.: 11/256,195

(22) Filed: Oct. 24, 2005

(51) Int. Cl. C23C 14/00

(52) U.S. Cl. 204/298.01; 204/298.12

(57) ABSTRACT

A sputtering target includes an outer target tube, an inner support tube of rectangular cross-sectional shape supporting a magnet carrier extending along substantially the entire length of the inner support tube; and a water cooling circuit including at least one passageway within said inner support tube with an inlet at one end thereof adapted to receive cooling water from an external source, at least one outlet aperture at an opposite end thereof opening to a chamber radially between the inner support tube and the outer target tube; and at least one cooling water outlet at the one end of the inner support tube.

This is a continuation-in-part of application Ser. No. ______ (Atty. Dkt. No. 3691.881), entitled: SPUTTERING TARGET AND METHOD/APPARATUS FOR COOLING THE TARGET, and application Ser. No. ______ (Atty. Dkt. No. 3691.883), entitled: SPUTTERING TARGET AND METHOD/APPARATUS FOR COOLING THE TARGET.

### BACKGROUND OF THE INVENTION

This invention relates to a sputtering target and, more specifically, to an internal magnet support tube configuration with cooling enhancement features.

The use of sputtering in order to deposit coatings on substrates is known in the art. For example, and without limitation, see U.S. Pat. Nos. 5,403,458; 5,317,006; 5,527,439; 5,591,314; 5,262,032; and 5,284,564. Briefly, sputter coating is an electric-discharge-type process which is conducted in a vacuum chamber in the presence of at least one gas. Typically, a sputtering apparatus includes a vacuum chamber, a power source, an anode, and one or more cathode targets which include material used to create a coating on an adjacent substrate. The target may include an outer tube enclosing a magnet bar assembly including an associated inner magnet bar support tube and a magnet carrier. More specifically, in certain known arrangements, the magnet bar is secured to the underside of the support tube along substantially the length of the support tube.

When an electrical potential is applied to the cathode target, the gas forms a plasma which bombards the target causing particles of the material from the target to leave the exterior surface of the outer target tube. These particles fall onto the substrate to thereby form the coating thereon. The outer target tube typically rotates about the stationary magnets supported by the inner support tube so that particles are “sputtered” uniformly from the entire periphery of the target tube as it rotates past the fixed magnet bar.

### BRIEF DESCRIPTION OF THE INVENTION

It has been found that non-uniform sputtering, i.e., non-uniform eroding of the target surface, is caused at least in part by non-uniform cooling of the interior surface of the outer target tube. Specifically, in a typical target water-cooling arrangement, cooling water flows through the inner magnet bar support tube and reverses direction to flow between the inner support tube and outer target tubes, it has been discovered that air bubbles and “dead water” zones are likely to form at or near the inner tube outlet jets where the cooling water reverses direction (sometimes referred to herein as the “flow-reversal zone”). It has also been discovered that insufficient circulation of cooling water along the inner magnet support bar (i.e., in the radial space or region between the magnet bar and target tube), further degrades the cooling of the target tube in this area. Resulting localized hot spots on the target tube surface can lead to non-uniform sputtering and decreased target component life.

In accordance with an exemplary embodiment of this invention, mechanical flow enhancement devices are attached to the external surface of the inner magnet bar support tube to promote and enhance cooling of the target tube. More specifically, two enhancement devices are provided that may be used alone or in combination to enhance cooling flow and thus promote more uniform sputtering.

The first device is a baffle in the form of a flat plate with an array of apertures formed therein. The baffle is secured to the exterior of the inner magnet bar support tube by any suitable fastening bracket adjacent that end of the inner support tube where the cooling water exits into the space between the inner and outer tubes. In this regard, the cooling water exits the inner tube in the form of a plurality of jets and almost immediately reverses direction to flow between the inner support tube and the outer target tube. By forcing the water to flow through the baffle, sufficient turbulence is created to avoid or at least reduce the creation of air bubbles and/or dead water zones at or near the cooling water flow-reversal zone.

The second device is a flow member in the form of spiral vane segments that are attached to the inner support tube and extend substantially the entire distance between the baffle and the opposite end of the inner and outer tubes. The series of discontinuous vane segments provide an axially extending space on the underside of the inner support tube to accommodate the axially extending magnet bar. The spiral vane segments cause the cooling water that otherwise might stagnate under the magnet bars to continuously circulate into and out of this region to thereby more uniformly cool the target or outer tube, and thus enhance sputter coating uniformity.

In addition, it has been found that an inner magnet bar support tube of rectangular cross-sectional shape reduces undesirable bending along the length of the support tube.

Both the baffle and spiral vane segments as described above may also be used with the rectangularly shaped magnet bar support tube with appropriate modifications.

Accordingly, in one aspect, the invention relates to a sputtering target comprising an outer target tube, an inner support tube of rectangular cross-sectional shape supporting a magnet carrier extending along substantially the entire length of the inner support tube; and a water cooling circuit including at least one passageway within the inner support tube with an inlet at one end thereof adapted to receive cooling water from an external source, at least one outlet aperture at an opposite end thereof opening to a chamber radially between the inner support tube and the outer target tube; and at least one cooling water outlet at the one end of the inner support tube.

In another aspect, the invention relates to a magnet bar support tube for use in a sputtering apparatus, the magnet bar support tube having a rectangular cross-sectional shape and supporting a magnet carrier extending substantially the entire length of the inner support tube.

In still another aspect, the invention relates to a sputtering target comprising an outer target tube, an inner support tube of rectangular cross-sectional shape supporting a magnet carrier extending along substantially the entire length of the inner support tube; a water cooling circuit including at least one passageway within the inner support tube with an inlet at one end thereof adapted to receive cooling water from an external source, at least one outlet aperture at an opposite end thereof opening to a chamber radially between the inner support tube and the outer target tube; a baffle comprising a substantially flat plate attached to the inner support tube adjacent the opposite end, the plate extending radially within the chamber between the inner support tube and the outer target tube and having an array of flow apertures therein; and a plurality of spiral vane segments attached to an outer surface of the inner support tube, downstream of the baffle in a direction of flow of water through the baffle.

The invention will now be described in detail, in connection with the drawings identified below.

### BRIEF DESCRIPTION OF THE DRAWINGS

FIG. 1 is a simplified and partially schematic side elevation of a conventional sputtering apparatus;

FIG. 2 is an end view of an inner magnet support bar and cooling flow baffle in accordance with an exemplary embodiment of the invention;

FIG. 3 is a partial side elevation of the inner magnet support bar shown in FIG. 2;

FIG. 4 is a section taken along the lines 4-4 in FIG. 3;

FIG. 5 is an end view of an inner magnet support bar in accordance with another exemplary embodiment of the invention;

FIG. 6 is a plan view of the inner magnet support bar shown in FIG. 5;

FIG. 7 is an end view of the inner magnet support bar shown in FIG. 5 but with a buffer plate added; and

FIG. 8 is an end view of the inner magnet support bar shown in FIG. 5 but with spiral vane segments added.

### DETAILED DESCRIPTION OF THE INVENTION

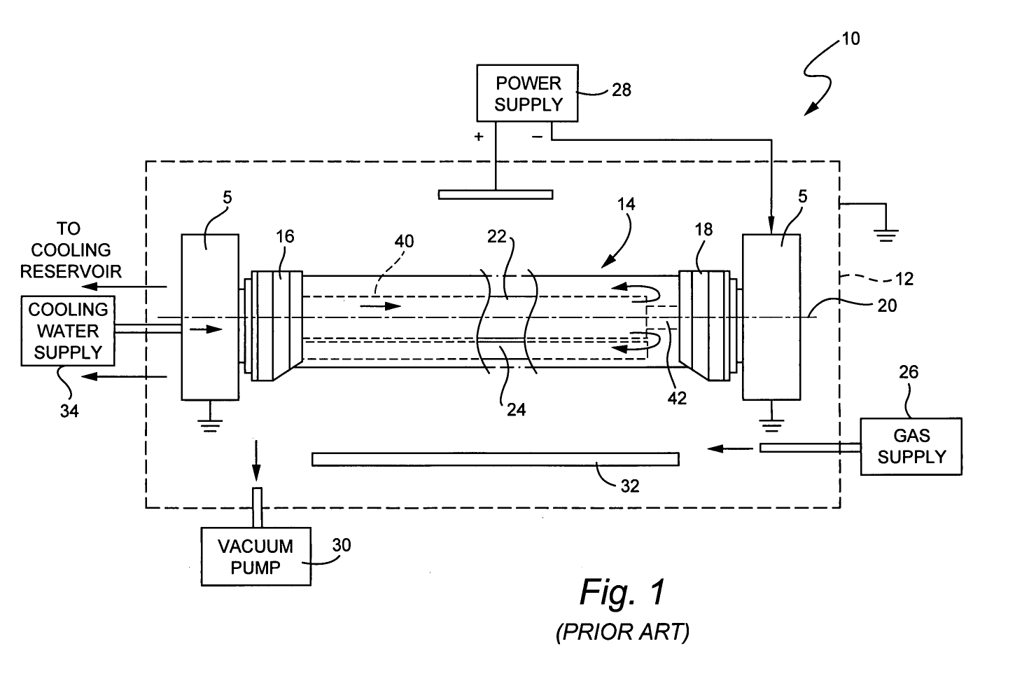

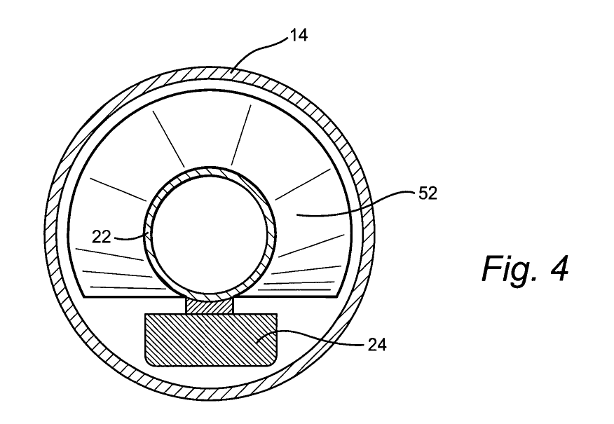

FIG. 1 illustrates in simplified form a conventional magnetron sputtering apparatus 10. The apparatus includes metal walls 12 of the vacuum chamber in which sputtering is performed; a cylindrical rotating target (or outer target tube) 14 that is supported at opposite ends by end blocks, i.e., a bearing block 16 and a drive block 18 so that the target is rotatable about axis 20; and an inner support tube 22 that supports the magnet carrier represented simplistically by the single block 24 in FIGS. 1-4) that extends along the underside of the inner support tube 22, substantially the entire length of both the inner support tube and the outer target tube. Gas is supplied to the vacuum tube via an external gas supply 26 while power is supplied via external power supply 28. The vacuum tube is evacuated by a vacuum pump 30.

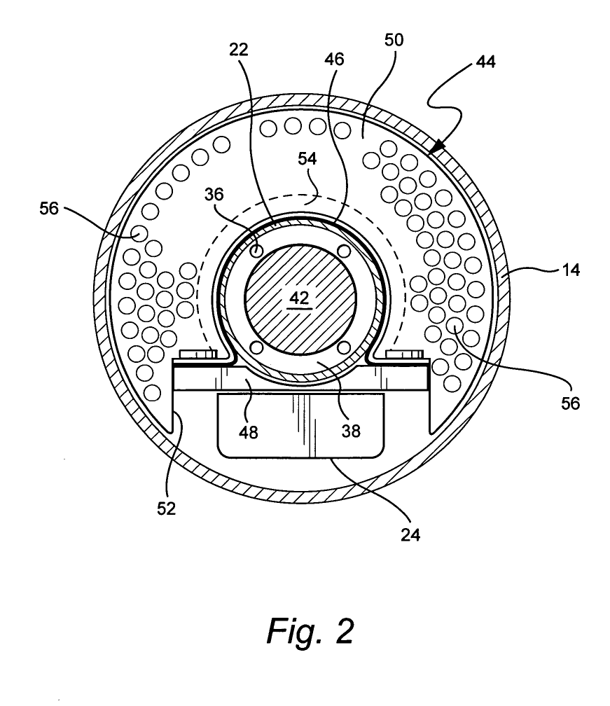

In a typical sputtering process, the plasma formed when an electrical potential is applied to the cathode target bombards the target and the dislodged particles fall on the substrate 32, forming a coating thereon. It is important that throughout the process, the target tube be cooled to a specified temperature. Accordingly, cooling water from a source 34 is introduced into the interior of the hollow inner support tube 22 at one end thereof through the bearing block 16, and exits the opposite end of the tube through a plurality of nozzle or jet apertures 36 provided in an end plate 38 (see FIG. 2). The apertures 36 may be arranged to emit streams parallel to the longitudinal axis of the target tube and/or at an acute angle thereto. The cooling water then reverses direction and flows back along the exterior of the inner tube 22, in the chamber or space 40 radially between the inner support tube 22 and the outer target tube 14, exiting the target tube via the same bearing block 16. Note that while the support tube 22 is terminated short of the drive block 18 to permit the cooling flow to exit the tube and reverse flow through the chamber 40, an inner spindle 42 that may be fixed to the end plate 38, supports the inner tube in the drive block 18. The particular manner in which the inner support tube 22 is mounted vis-à-vis the rotatable target tube 14 is not of particular significance to the invention described herein.

This invention relates to devices employed to enhance the cooling of the target tube 14. With reference to FIG. 2, one example of such a device is in the form of a baffle 44 attached by tube clamp-type bracket components 46, 48 and suitable fasteners (or equivalents) to the exterior surface of the inner support tube 22. The baffle 44 is located at the end of the inner support tube 22 where the cooling water exits the inner support tube and is thus adjacent and downstream of the flow-reversal zone.

Baffle 44 in the example disclosed is composed of a flat, generally circular metal plate 50 that is designed to generally surround the inner tube 22, but with a generally rectangular cut-out 52 that accommodates the magnet bar array 24. Note also that the baffle plate is solid about an inner peripheral band portion 54, thus blocking flow at the radially innermost portion of the cooling flow path between the inner and outer tubes. The remaining area of the baffle plate is provided with a dense array of flow apertures 56. The array of apertures extends approximately 270° about the inner tube, from one side of the cut out 52 to the opposite side of the cut-out. Thus, after the streams of water exit the nozzle or jet apertures 36 in the end plate 38, the cooling water reverses direction and flows immediately through the array of apertures 56 in the baffle 44 and into the chamber or space 40. The presence of band portion 54 forces the cooling water to flow radially away from the inner support tube 22, ensuring more cooling flow closer to the target tube 14. The baffle 44 also increases the flow velocity above and below the magnet carrier 24 and creates a significant degree of turbulence adjacent the drive block 18, thereby establishing good mixture of the radially inner and outer flows and eliminating dead water zones at or adjacent the flow-reversal zone. At the same time, rotation of the target tube 14 reduces bubble adhesion on the inner support tube wall.

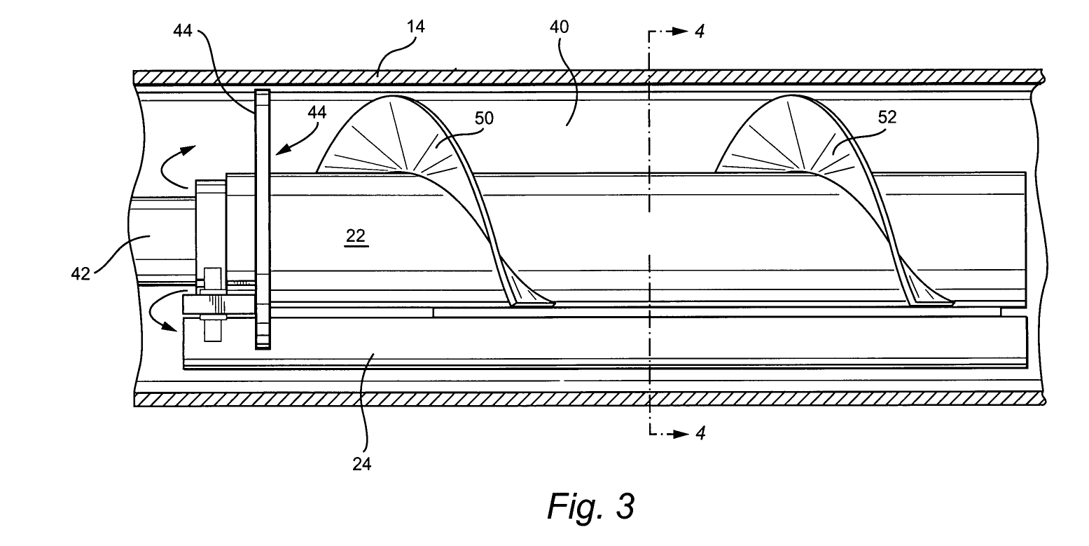

A second structural member promotes good circulation along the entire length of the inner support tube 22. With reference especially to FIG. 3, a plurality of spiral vane segments 50, 52, etc. are attached by welding or other suitable means to the exterior surface of the inner tube 22. The segments are aligned or oriented so as to establish a substantially continuous spiral flow path extending from a location adjacent the baffle 44 to the opposite end of the inner tube 22. The spaces between the segments 50, 52, etc., are aligned along the underside of the inner support tube 22 to provide the space necessary to accommodate the magnet carrier 24. The spiral vane segments 50, 52, etc., extend radially substantially the same distance as the baffle, with only a generous tolerance between the baffle 44 and vane segments 50, 52, etc., and the ID of the target tube 14 to enhance circulation but also to preclude any abrasion of the target tube inner wall. Thus, after passing through the apertures 56, the cooling water is forced to flow along the spiral path established by the vane segments 52.

The spiral vane segments 52 promote good circulation of the cooling water along the entire length of the target tube, and insure continuous flow of cooling water into and out of the region of the plenum below the magnet bar(s). This arrangement also reduces bubble adhesion all along the length of the inner support tube and magnet bar(s).

Another aspect of the present invention is the re-shaping of the inner support tube and the “decoupling” of the magnet carrier from the inner support tube. Specifically, differently-shaped support bars result in varying mechanical stability and, in this instance, bending along the longitudinal axis is of principal concern. Comparisons of various inner support tube shapes are set out in Table I below in terms of maximum bending and weight for inner support bars of similar wall thickness and overall length.

| structural shape | bending | weight |
|---|---|---|
| circular tube | 14.8 mm | 58 kg |
| square tube | 10.8 mm | 58 kg |
| Square tube with angle plates | 6.7 mm | 74 kg |
| rectangular tube | 3.8 mm | 63 kg |

A noticeable improvement in bending resistance is apparent for rectangular tubes, where bending along the entire length of the inner support tube is reduced to 3.8 mm.

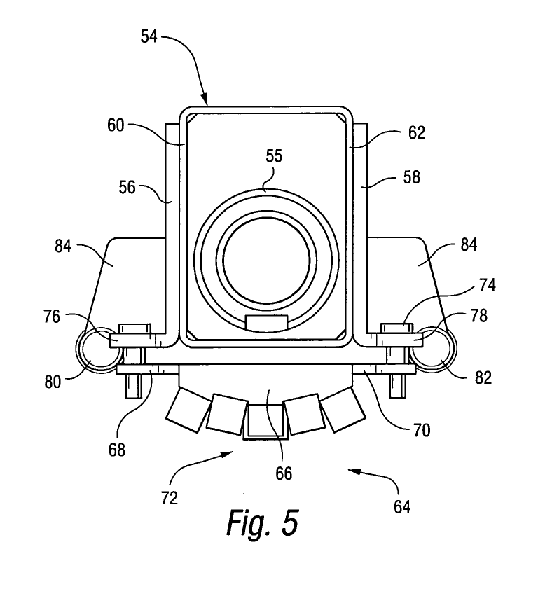

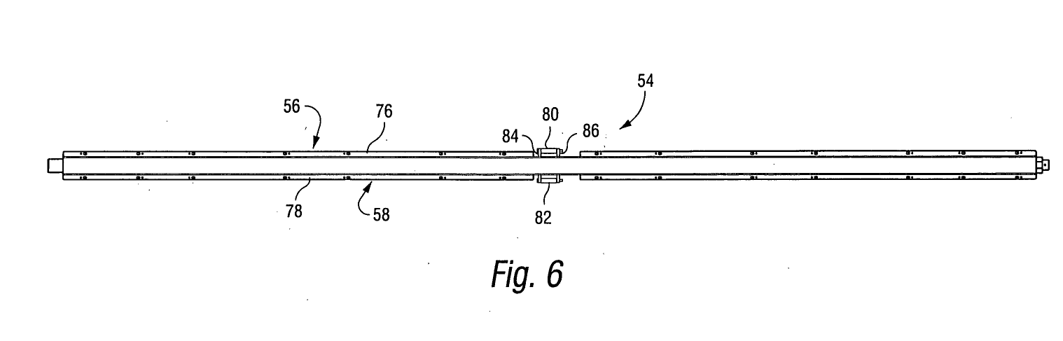

FIGS. 5 and 6 illustrate an inner support tube 54 of rectangular cross-sectional shape, with the height dimension greater than the width dimension (the exact dimensions may vary to suit particular applications).

The inner support tube 54 in this example is supported within end blocks by spindles (one shown at 55), and rigidified by a pair of angle braces 56, 58 welded to the opposite sides 60, 62, respectively, of the tube 54. The braces 56, 58 extend along substantially the entire length of the tube 54. The magnet bar assembly 64, including carrier 66, attachment flanges 68, 70 and magnet array 72, is suspended from the underside of the tube 54 by bolts or other suitable fasteners 74 that pass through the angle brace flange portions 76, 78 and the attachment flanges 68, 70 at axially-spaced locations along the length of the carrier 66. By “decoupling” of the magnet carrier 66 from the inner support tube 54, any bending of the inner support bar 54, due to gravity, is minimized if not eliminated in the magnet carrier 66. Similarly, any tension caused by tuning of the magnets (typically done by inserting metal pieces beneath the magnets) is not transferred to the support bar as a result of this “decoupling”.

A pair of rollers 80, 82 may be located near the center of the tube 54, each supported by a pair of angle plates 84, 86. These rollers are designed to prevent the magnet bar array from contacting the interior surface of the round target tube in the event of any bending, the maximum degree of which would occur at this location. In alternative arrangements, particularly in the case of extended length targets, additional roller pairs may be utilized at desired intervals.

It will be appreciated that the rectangularly-shaped support tube could also be rigidified in other ways, for example, by increasing the thickness of the tube or by other added reinforcements.

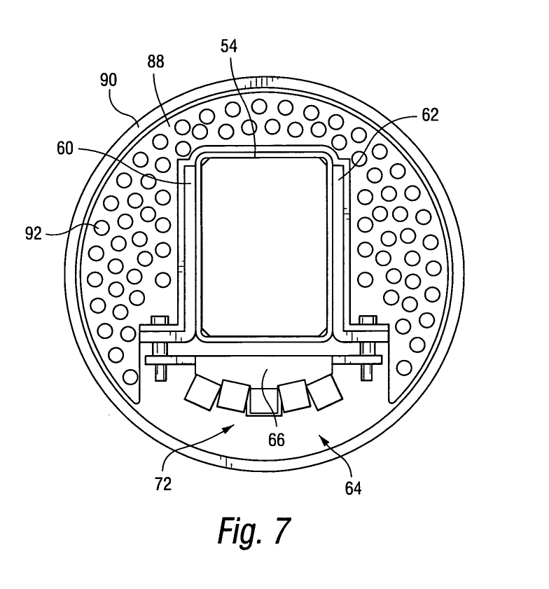

FIG. 7 illustrates the rectangular support tube 54 with a baffle plate 88 fixed thereto and assembled within a target tube 90 that is similar in all respects to the baffle plate 44 described hereinabove, with the exception that the plate 88 is configured to surround a rectangular rather than round tube. The location of the baffle pattern of apertures 92, and its functional aspects remain substantially as described above.

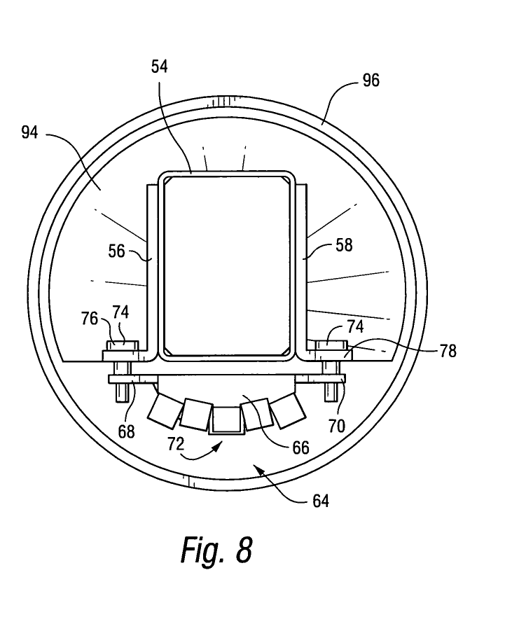

FIG. 8 illustrates the rectangular support tube 54 with a plurality of spiral vane segments 94 secured thereto, and assembled within a target tube 96. Here again, the configuration and function of the vane segments remain as stated hereinabove. The principal difference lies in the rectangular cut-out shape where the vane segments are joined to the tube 54 and angle braces 56, 58. As in the earlier described embodiment, the baffle plate 88 and spiral vane segments 96 may be utilized together on the tube 54, in substantially the same spatial arrangement as shown in FIG. 3.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A sputtering target comprising an outer target tube, an inner support tube of rectangular cross-sectional shape supporting a magnet carrier extending along substantially the entire length of the inner support tube; and a water cooling circuit including at least one passageway within said inner support tube with an inlet at one end thereof adapted to receive cooling water from an external source, at least one outlet aperture at an opposite end thereof opening to a chamber radially between said inner support tube and said outer target tube; and at least one cooling water outlet at said one end of said inner support tube.

2. The sputtering target of claim 1 wherein said magnet carrier supports a plurality of magnets, and wherein said carrier is suspended below said inner support tube via fasteners at axially-spaced locations therealong.

3. The sputtering target of claim 1 wherein said outer target tube is rotatable about said inner support tube.

4. The sputtering target of claim 1 wherein said inner support tube has a height greater than a width thereof.

5. The sputtering target of claim 1 wherein said inner support tube is rigidified by a pair of angle braces attached respectively to opposite external sides of said inner support tube.

6. The sputtering target of claim 5 wherein each angle brace includes a horizontal flange and wherein said magnet carrier is formed with axially-spaced attachment flanges, with a plurality of fasteners extending between said horizontal flanges and said attachment flanges to thereby secure said carrier to said inner support tube.

7. A magnet bar support tube for use in a sputtering apparatus, the magnet bar support tube having a rectangular cross-sectional shape and supporting a magnet carrier extending substantially the entire length of said inner support tube.

8. The magnet bar support tube of claim 7 wherein said magnet carrier supports an array of magnets.

9. The magnet bar support tube of claim 7 wherein at least one roller pair is attached to opposite respective sides of said inner support tube.

10. The magnet bar support tube of claim 7 wherein said support tube is provided with a cooling water inlet at one end thereof and at least one or more cooling water outlets at an opposite end thereof.

11. The magnet bar support tube of claim 7 wherein said magnet carrier is suspended below said inner support tube by a plurality of axially-spaced fasteners.

12. The magnet bar support tube of claim 7 wherein said support tube has a height greater than a width thereof.

13. The magnet bar support tube of claim 7 wherein said support tube is rigidified by a pair of angle braces attached respectively to opposite external sides of said support tube.

14. The magnet bar support tube of claim 7 wherein said magnet carrier supports an array of magnets.

15. The magnet bar support tube of claim 7 and further comprising a baffle comprising a substantially flat plate attached to said support tube adjacent one end thereof, said plate extending radially outwardly and having an array of flow apertures therein.

16. The magnet bar of claim 15 wherein said plate includes a solid non-apertured band in a region adjacent said support tube.

17. The magnet bar support tube of claim 7 and further comprising at least one spiral vane segment attached to an outer surface of said support tube.

18. The magnet bar support tube of claim 17 wherein said at least one spiral vane segment comprises a plurality of axially spaced segments along substantially the entire length of said support tube.

19. The magnet bar support tube of claim 18 wherein said plurality of axially spaced vane segments are aligned to establish a substantially continuous spiral flow path along said support tube.

20. A sputtering target comprising an outer target tube, an inner support tube of rectangular cross-sectional shape supporting a magnet carrier extending along substantially the entire length of the inner support tube; a water cooling circuit including at least one passageway within said inner support tube with an inlet at one end thereof adapted to receive cooling water from an external source, at least one outlet aperture at an opposite end thereof opening to a chamber radially between said inner support tube and said outer target tube; a baffle comprising a substantially flat plate attached to said inner support tube adjacent said opposite end, said plate extending radially within said chamber between said inner support tube and said outer target tube and having an array of flow apertures therein; and a plurality of spiral vane segments attached to an outer surface of said inner support tube, downstream of said baffle in a direction of flow of water through said baffle.
